(19) United States
(12) Patent Application Publication
(10) Pub. No.: US 2015/0014639 A1
(43) Pub. Date: Jan. 15, 2015

(54) ORGANIC LIGHT EMITTING DIODE DISPLAY HAVING REDUCED POWER CONSUMPTION

(71) Applicant: Samsung Display Co., Ltd., Yongin-City (KR)

(72) Inventors: Jin-Koo CHUNG, Yongin-City (KR); Jun-Ho CHOI, Yongin-City (KR); Ho-Ryun CHUNG, Yongin-City (KR)

(73) Assignee: Samsung Display Co., Ltd., Yongin-City (KR)

(21) Appl. No.: 14/105,838

(22) Filed: Dec. 13, 2013

(30) Foreign Application Priority Data
Jul. 15, 2013 (KR) 10-2013-0083018

(51) Int. Cl. H01L 27/32

(52) U.S. Cl. CPC H01L 27/3211
USPC 257/40

(57) ABSTRACT

An OLED display according to an exemplary embodiment includes: a substrate; a plurality of thin film transistors formed on the substrate; unit pixels formed on the thin film transistors and including first to third organic emission layers which are at least parts of respective sub-pixels; a first common electrode formed on the first organic emission layer; a second common electrode formed on the second organic emission layer; and a third common electrode formed on the third organic emission layer, wherein the first and second common electrodes are electrically insulated from each other.

### CROSS-REFERENCE TO RELATED APPLICATION

This application claims priority to, and the benefit of, Korean Patent

Application No. 10-2013-0083018 filed in the Korean Intellectual Property Office on Jul. 15, 2013, the entire contents of which are incorporated herein by reference.

### BACKGROUND OF THE INVENTION

(a) Field of the Invention

The present disclosure relates generally to flat panel displays. More specifically, the present disclosure relates to an organic light emitting diode (OLED) display having reduced power consumption.

(b) Description of the Related Art

Display devices which are currently known include a liquid crystal display (LCD), a plasma display panel (PDP), an organic light emitting diode (OLED) display, a field effect display (FED), and an electrophoretic display device.

The OLED display includes a pixel electrode, a common electrode, and an organic emission layer disposed between the pixel electrode and the common electrode. Electrons injected from one electrode are coupled with holes injected from another electrode on the organic emission layer to form excitons, where each excitors emits light when it enters a ground state.

In addition, each pixel formed in the substrate of the OLED display includes sub-pixels of green, red, and blue colors. In this case, a common electrode is formed on an organic emission layer forming each sub-pixel.

Conventionally, a single common electrode is formed on every organic emission layer. Accordingly, although organic emission layers require different levels of driving voltages depending on colors, the respective organic emission layers are supplied with the same voltage, thereby resulting in excessive power consumption.

The above information disclosed in this Background section is only for enhancement of understanding of the background of the invention and therefore it may contain information that does not form the prior art that is already known in this country to a person of ordinary skill in the art.

### SUMMARY

The present invention has been made in an effort to provide an OLED display of which organic emission layers of different colors are supplied with different levels of driving voltages.

An OLED display according to an exemplary embodiment of the present invention includes: a substrate; a plurality of thin film transistors formed on the substrate; unit pixels formed on the thin film transistor and including first to third organic emission layers which are at least parts of respective sub-pixels; a first common electrode formed on the first organic emission layer; a second common electrode formed on the second organic emission layer; and a third common electrode formed on the third organic emission layer, wherein the first and second common electrodes are electrically insulated from each other.

In this case, the third common electrode may be connected to the second common electrode.

The first to third organic emission layers may be at least parts of red, green, and blue sub-pixels, respectively.

The first to third common electrodes may be formed in the same layer.

In this case, the first to third common electrodes may be made of the same material.

The third common electrode may be insulated from the first and second common electrodes.

The first to third organic emission layers may be at least parts of red, green, and blue sub-pixels, respectively.

The OLED display may further include an input pad formed between the third common electrode and the substrate, and configured to supply a voltage to the third common electrode.

Each thin film transistor may include a semiconductor layer, a gate electrode, a source electrode, and a drain electrode, and the input pad may be formed in the same layer of one of the gate electrode, the source electrode, and the drain electrode of at least one of the thin film transistors.

The input pad may be made of the same material as the one of the gate electrode, the source electrode, and the drain electrode of the at least one of the thin film transistors.

In another embodiment, an organic light emitting diode (OLED) display comprises a substrate; a plurality of sub-pixels formed on the substrate, each of the sub-pixels having an emission layer configured to emit light; a first common electrode formed on the emission layers of a first group of the sub-pixels; and a second common electrode formed on the emission layers of a second group of the sub-pixels.

The first and second common electrodes may be electrically insulated from each other.

The first group of the sub-pixels may comprise red sub-pixels. The second group of the sub-pixels may comprise blue and green sub-pixels.

The OLED display may further comprise a third common electrode formed on the emission layers of a third group of the sub-pixels, wherein the third common electrode is electrically insulated from both the first and second common electrodes.

The third group of the sub-pixels may comprise blue sub-pixels.

In the OLED display according to the exemplary embodiment of the present invention, the respective organic emission layers of different colors are supplied with different levels of driving voltages so that power consumption of the OLED display can be reduced.

### BRIEF DESCRIPTION OF THE DRAWINGS

FIG. 1 is a layout view of a plurality of pixels in an OLED display.

FIG. 2 is a cross-sectional view of the OLED display of FIG. 1, taken along the line II-II, where one common electrode is formed on first to third organic emission layers in the OLED display.

FIG. 3 is a layout view of an OLED display according to an exemplary embodiment.

FIG. 4 is a cross-sectional view of the OLED display of FIG. 3, taken along the line IV-IV.

FIG. 5 is a layout view of an OLED display according to another exemplary embodiment.

FIG. 6 is a cross-sectional view of the OLED display FIG. 5, taken along the line VI-VI.

### DETAILED DESCRIPTION OF THE EMBODIMENTS

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention. The drawings and description are to be regarded as illustrative in nature and not restrictive. Like reference numerals designate like elements throughout the specification.

Further, a size or a thickness of each component illustrated in the drawings is arbitrarily selected for better understanding and ease of description, and the present invention is not limited to the illustrated size or thickness.

In the drawings, the thickness of layers, films, panels, regions, etc., are exaggerated for clarity. Further, in the drawings, for better understanding and ease of description, a thickness of some layers and regions is exaggerated. It will be understood that when an element such as a layer, film, region, or substrate is referred to as being “on” another element, it can be directly on the other element or intervening elements may also be present.

In addition, unless explicitly described to the contrary, the word “comprise” and variations such as “comprises” or “comprising” will be understood to imply the inclusion of stated elements but not the exclusion of any other elements. Further, in the specification, the word “on” means positioning on or below the object portion, but does not essentially mean positioning on the upper side of the object portion based on a gravity direction.

Various features of the disclosed embodiments, as well as others, can be employed in various combinations, all falling within the scope of the invention.

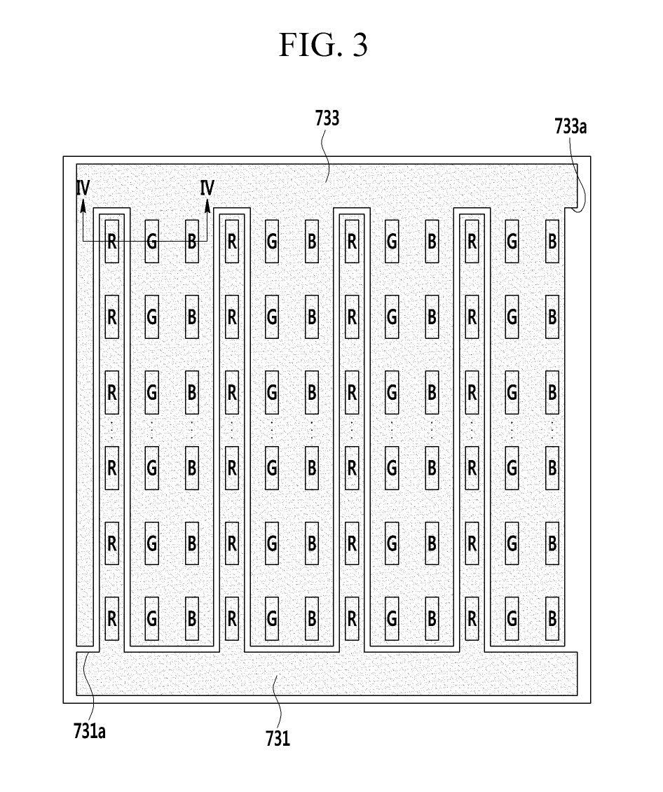

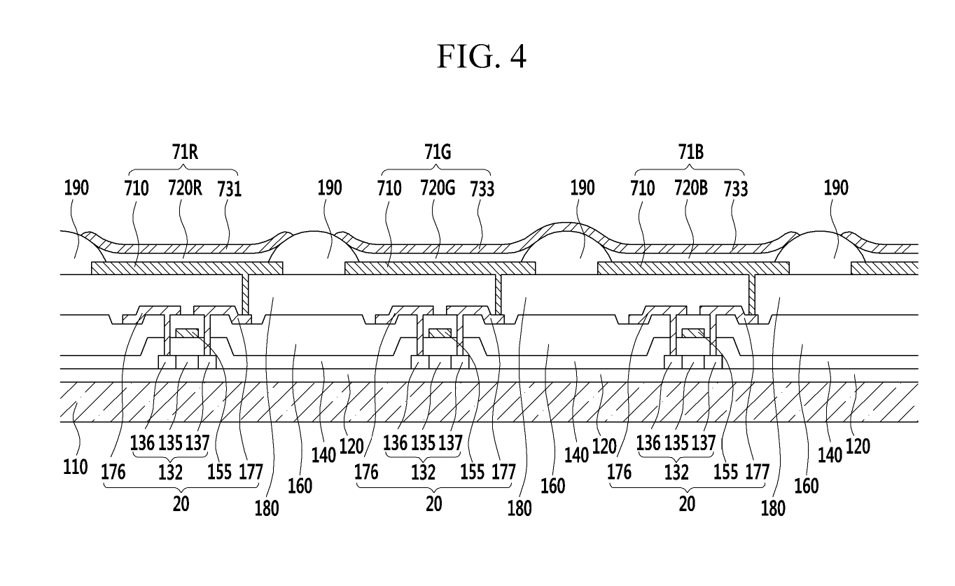

Referring to FIG. 3 and FIG. 4, an organic light emitting diode (OLED) display according to an exemplary embodiment can control organic emission layers forming a plurality of sub-pixels to be supplied with different voltages by forming common electrodes respectively covering the organic emission layers in an insulated manner.

Referring to FIG. 3 and FIG. 4, the OLED display according to the exemplary embodiment includes a substrate 110, one or more thin film transistors 20, first to third organic emission layers 720R, 720G, and 720B, and first to third common electrodes 731, 733, and 733. Here, the second and third common electrodes 733, 733 are parts of a single unitary whole (although this need not necessarily be the case, and the two electrodes 733, 733 can be separate electrodes that are electrically connected). The two electrodes 733, 733 are distinguished by the different sub-pixels they cover. Here, each of the two electrodes 733, 733 covers sub-pixels of different color.

In the following description, a thin film transistor applied to the OLED display will be described, focusing on a driving thin film transistor as between a switching thin film transistor and a driving thin film transistor.

Referring to FIG. 4, the substrate 110 may be formed of an insulating material such as glass, quartz, ceramic, plastic, and the like. However, the present invention is not limited thereto, and the substrate 110 may be formed as a metallic substrate made of stainless steel and the like.

In addition, a buffer layer 120 is formed on the substrate 110. The buffer layer 120 prevents permeation of impurity elements and smoothes the surface of the substrate 110. In this case, the buffer layer 120 may be made of various known materials that can perform the above-stated functions.

Driving semiconductor layers 132 are formed on the buffer layer 120. Each driving semiconductor layer 132 is formed from a polysilicon layer. In addition, each driving semiconductor layer 132 includes a channel area 135 in which impurities are not doped, and a source area 136 and a drain area 137 formed at respective sides of the channel area 135. The source area 136 and the drain area 137 are p+ doped.

Meanwhile, a gate insulating layer 140 is formed on each of the driving semiconductor layers 132. The gate insulating layer 140 may be made of a silicon nitride SᵢNₓ or a silicon oxide SᵢOₓ.

In addition, gate wires including driving gate electrodes 155 are formed on the gate insulating layer 140. In this case, each driving gate electrode 155 overlaps at least a part of the driving semiconductor layer 132, particularly, the channel area 135.

Interlayer insulating layers 160 that cover the driving gate electrodes 155 are formed on the gate insulating layer 140. The gate insulating layer 140 and the interlayer insulating layer 160 have through-holes that expose the source areas 136 and the drain electrodes 137 of each driving semiconductor layer 132. In this case, like the gate insulating layer 140, the interlayer insulating layer 160 is formed using a ceramic-based material such as a silicon nitride SᵢNₓ or a silicon oxide SᵢOₓ.

In addition, data wires including a driving source electrode 176 and a driving drain electrode 177 are formed on the interlayer insulating layer 140 over each transistor 20. In this case, the driving source electrode 176 and the driving drain electrode 177 are respectively connected to the source area 136 and the drain area 137 of the driving semiconductor layer 132 through through-holes formed in the interlayer insulating layer 160 and the gate insulating layer 140.

As described, a driving thin film transistor 20 including the driving semiconductor layer 132, the driving gate electrode 155, the driving source electrode 176, and the driving drain electrode 177 is formed. The configuration of the driving thin film transistor 20 is not limited to the above-stated example, and may be any other suitable transistor configuration, as will be understood by one of ordinary skill in the art.

Meanwhile, planarization layers 180 covering the data wires 176 and 177 are formed on the respective interlayer insulating layers 160. Each planarization layer 180 planarizes the surface over the data wires 176 and 177, to improve luminous efficiency of organic light emitting elements 71R, 71G, and 71B that are formed on the planarization layer 180. In this case, the planarization layer 180 includes electrode contact holes that partially expose each driving drain electrode 177.

Pixel electrodes 710 of the organic light emitting elements 71R, 71G, and 71B are formed on the planarization layers 180. That is, the OLED display includes a plurality of pixel electrodes 710 respectively arranged in each of the plurality of sub-pixels.

Referring to FIG. 4, the pixel electrodes 710 are disposed at a distance from each other. A single pixel electrode 710 is provided in each of the organic light emitting elements 71R, 71G, and 71B. In this case, each pixel electrode 710 is connected to its drain electrode 177 through an electrode contact hole 182 formed in the planarization layer 180.

In addition, a pixel defining layer 190 having openings that expose each pixel electrode 710 is formed on the planarization layer 180. That is, the pixel defining layer 190 includes a plurality of openings formed over and defining the respective sub-pixels. The pixel electrodes 710 are disposed to correspond to the openings of the pixel defining layer 190.

Organic emission layers 720R, 720G, and 720B are formed on the pixel electrodes 710, and common electrodes 731 and 733 are formed on the organic emission layers layer 720R, 720G, and 720B. Thus, the organic light emitting elements 71R, 71G, and 71B that include the pixel electrode 710, the organic emission layers 720R, 720G, and 720B, and the common electrodes 731 and 733 are formed.

The organic emission layers 720R, 720G, and 720B are made of a low molecular organic material or a high molecular organic material. In addition, the organic emission layers 720R, 720G, and 720B may respectively be formed in a multilayer configuration including an emission layer and at least one of a hole injection layer (HIL), a hole transport layer (HTL), an electron transport layer (ETL), and an electron injection layer (EIL). In a case where the organic emission layers 720R, 720G, and 720B include each of these layers, the hole-injection layer (HIL) is disposed on the pixel electrode 710 which is the anode, and the hole-transporting layer (HTL), the emission layer, the electron-transporting layer (ETL), and the electron-injection layer (EIL) are sequentially stacked thereon.

Meanwhile, the organic emission layers 720R, 720G, and 720B are distinguished with colors such as red, green, blue, and the like according to a material and a type of the emission layer. In the description of the OLED display according to the exemplary embodiment, the organic emission layer 720R, the organic emission layer 720G, and the organic emission layer 720B will be respectively described as a red organic emission layer 720R, a green organic emission layer 720G, and a blue organic emission layer 720B.

The pixel electrodes 710 and the common electrodes 731 and 733 may respectively be made of a transparent conductive material or a semi-transmissive or a reflective conductive material. Depending on the type of the material of the pixel electrodes 710 and the common electrodes 731 and 733, the OLED display may be classified as a front emission type, a bottom emission type, or a dual emission type of OLED display.

Referring to FIG. 3 and FIG. 4, according to this exemplary embodiment, a first common electrode 731 disposed on the organic emission layer 720R may be insulated from second and third common electrodes 733 respectively disposed on the organic emission layers 720G and 720B. In further detail, the first common electrode 731 is separated (i.e., electrically insulated) from the second and third common electrodes 733.

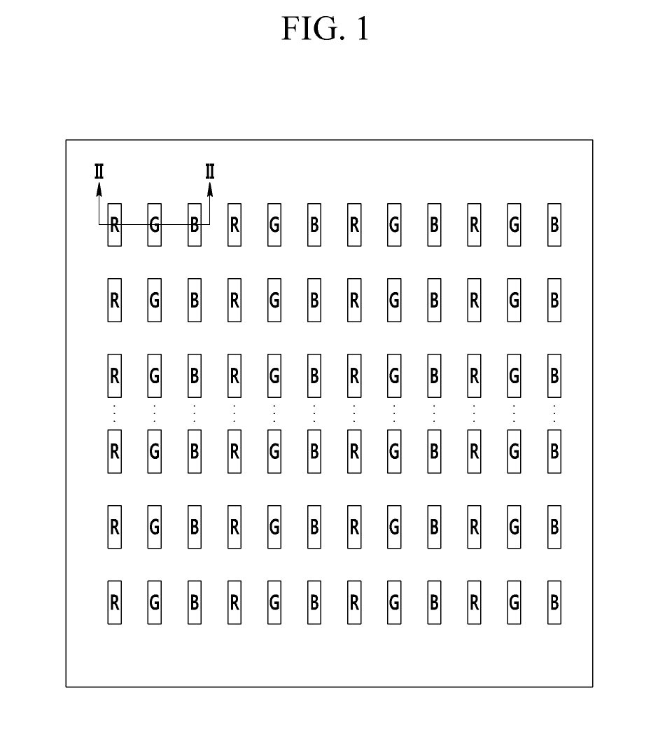

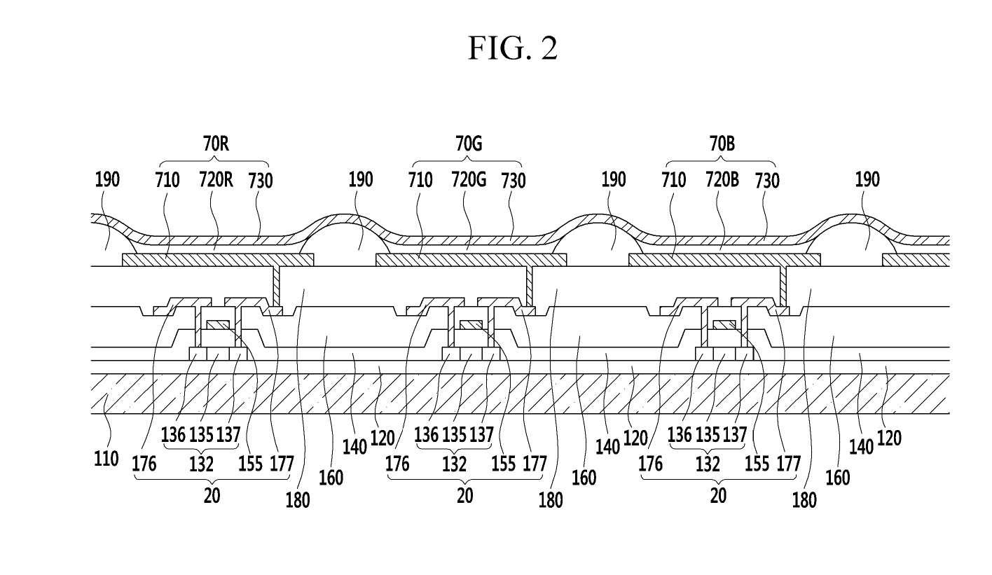

Now, an insulation structure of the common electrodes 731 and 733 will be described in comparison with a structure of common electrodes of a general OLED display of FIG. 1 and FIG. 2.

FIG. 1 shows alignment of a plurality of pixels in a substrate of an OLED display. In FIG. 1, R, G, and B respectively show organic emission layers 720R, 720G, and 720B of FIG. 2. In the embodiment of FIGS. 3 and 4, multiple common electrodes are formed on the organic emission layers 720R, 720G, and 720B.

However, in FIG. 1 and FIG. 2, a single common electrode 730 is formed on the organic emission layers 720R, 720G, and 720B. That is, the single common electrode 730 covers all the organic emission layers 720R, 720G, and 720B. Accordingly, the organic emission layers 720R, 720G, and 720B are respectively supplied with the same driving voltage through the common electrode 730. Thus, although the organic emission layers 720R, 720G, and 720B require different driving voltages for different light emission colors, they are supplied with the same driving voltage.

However, in the embodiment of FIGS. 3 and 4, the common electrodes 731 and 733 formed on the organic emission layers 720R, 720G, and 720B are formed to be insulated from each other according to the organic emission layers 720R, 720G, and 720B respectively disposed therebelow.

Referring to FIG. 3, the first common electrode 731 is formed on the red organic emission layers 720R. In addition, the common electrodes 733 respectively formed on the green organic emission layers 720G and the blue organic emission layers 720B are formed as a single common electrode 733. That is, a single common electrode 733 covers the organic emission layers 720G and 720B. Thus, the second common electrode 733 and the third common electrode 733 of FIG. 4 are connected to each other.

Accordingly, the first common electrode 731 is insulated from the second common electrode 733. Also, the first common electrode 731 is insulated from the third common electrode 733. Therefore, a driving voltage supplied through the first common electrode 731 may be different from a driving voltage supplied through the second and third common electrodes 733.

For example, in the OLED display, the red organic emission layer, the green organic emission layer, and the blue organic emission layer may be respectively supplied with driving voltages of 5.2 V, 4.4 V, and 4.4 V. When the common electrodes are provided as a single common electrode, a driving voltage should be supplied as the highest driving voltage with reference to the red organic emission layer, even though the organic emission layers require different levels of driving voltages.

However, according to the exemplary embodiment, since the common electrodes of the red organic emission layer and the green organic emission layer (also including the blue organic emission layer) are insulated from each other, the red organic emission layer and the green organic emission layer (also including the blue organic emission layer) can be supplied with different levels of driving voltages.

In this case, the first common electrode 731 may include a first input terminal 731a that is supplied with a voltage from an external source. In addition, the second and third common electrodes 733 may include a second input terminal 733a. Thus, the first common electrode 731 and the second and third common electrodes 733 can be supplied with different levels of driving voltages respectively though the first input terminal 731a and the second input terminal 733a.

Meanwhile, the common electrodes 731 and 733 respectively formed on the organic emission layers 720R, 720G, and 720B may be formed of the same layer. In a process for layering the common electrodes, separated patterns may be used to form the first common electrode 731 and the second common electrodes 733, as shown in FIG. 3.

Further, the first to third common electrodes 731 and 733 may be made of the same material. As described above, the first to third common electrodes 731 and 733 may be made of a transparent conductive material or a semi-transmissive or reflective conductive material.

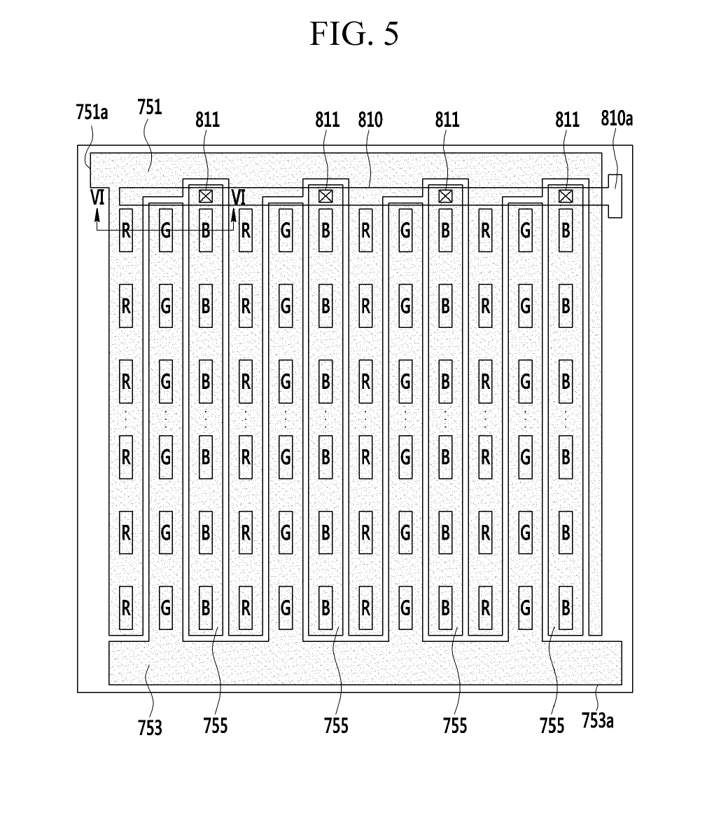

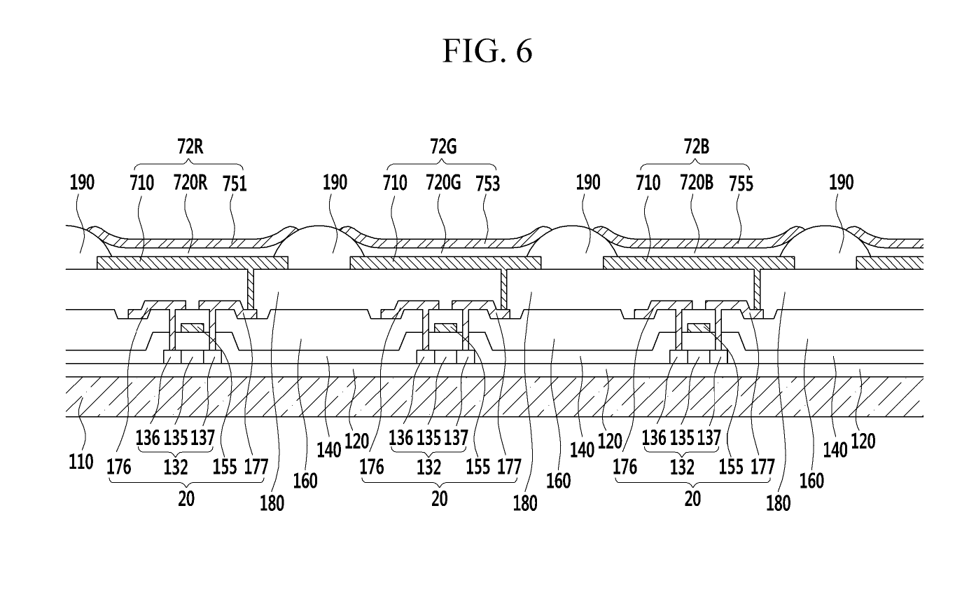

Referring to FIG. 5 and FIG. 6, in an OLED display according to another exemplary embodiment, first to third common electrodes 751, 753, and 755 are formed to be insulated from each other. That is, as shown in FIG. 5, the first to third common electrodes 751, 753, and 755 are separated and spaced apart from each other.

According to the present exemplary embodiment, the first to third common electrodes 751, 753, and 755 are respectively disposed on first to third organic emission layers 720R, 720G, and 720B. In this case, the first to third common electrodes 751, 753, and 755 are insulated from each other. That is, unlike the second and third common electrodes 733 of FIG. 3 and FIG. 4, the second and third common electrodes 753 and 755 of the present exemplary embodiment are insulated from each other.

Accordingly, the first to third organic emission layers 720R, 720G, and 720B can be supplied with different levels of driving voltages by the insulated first to third common electrodes 751, 753, and 755.

Thus, when the first to third organic emission layers 720R, 720G, and 720B of red, green, and blue colors require different driving voltages, they can be supplied with respectively corresponding levels of driving voltages.

In this case, the first common electrode 751 may include a first input terminal 751a that can be supplied with a voltage from an external source. In addition, the second common electrode 753 also can be supplied with a voltage from an external source through a second input terminal 753a.

Referring to FIG. 5, an input pad 810 may further be included to supply a driving voltage to the third common electrode 755. In this case, the input pad 810 may be formed below the third common electrode 755.

The input pad 810 may be formed of the same layer of one of a gate electrode 155, a source electrode 176, and a drain electrode 177. That is, the input pad 810 and one of the gate electrode 155, the source electrode 176, and the drain electrode 177 may be substantially simultaneously formed.

In addition, the input pad 810 may be made of the same material as that of the gate electrode 155, source electrode 176, or drain electrode 177.

For example, when the input pad 810 is formed of the same material as the gate electrode 155, the input pad 810 may be formed when the gate electrode 155 is layered. In this case, the input pad 810 may be made of the same material as the gate electrode 155.

Meanwhile, an insulation layer may be formed between the input pad 810 and the common electrodes. The insulation layer is provided to prevent the input pad 810 from being connected with the first and second common electrodes 751 and 753.

In this case, openings 811 that expose the input pad 810 may be formed in the insulation layer to connect the input pad 810 with the third common electrodes 755. In addition, a third input terminal 810a may be formed in the input pad 810 for receiving a voltage from an external source. Therefore, the voltage input through the third input terminal 810a may be supplied to the third common electrodes 755 through the input pads 810.

In the OLED display of the exemplary embodiments, the common electrodes formed on the organic emission layers are formed to be insulated from each other to provide different levels of driving voltages to the organic emission layers of different colors, to thereby reduce power consumption of the OLED display.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

<Description of Symbols>

| | |
|---|---|
| 20: thin film transistor | 110: substrate |
| 132: semiconductor layer | 155: gate electrode |
| 176: source electrode | 177: drain electrode |
| 720R: first organic emission layer | 720G: second organic emission layer |
| 720B: third organic emission layer | 731, 751: first common electrode |
| 733, 753: second common | 755: third common electrode |
| electrode | |

What is claimed is:

1. An organic light emitting diode (OLED) display comprising:
a substrate;
a plurality of thin film transistors formed on the substrate;
unit pixels formed on the thin film transistors and including first to third organic emission layers which are at least parts of respective sub-pixels;
a first common electrode formed on the first organic emission layer;
a second common electrode formed on the second organic emission layer; and
a third common electrode formed on the third organic emission layer,
wherein the first and second common electrodes are electrically insulated from each other.

2. The OLED display of claim 1, wherein the third common electrode is connected to the second common electrode.

3. The OLED display of claim 2, wherein the first to third organic emission layers are at least parts of red, green, and blue sub-pixels, respectively.

4. The OLED display of claim 1, wherein the first to third common electrodes are formed in the same layer.

5. The OLED display of claim 4, wherein the first to third common electrodes are made of the same material.

6. The OLED display of claim 1, wherein the third common electrode is insulated from the first and second common electrodes.

7. The OLED display of claim 6, wherein the first to third organic emission layers are at least parts of red, green, and blue sub-pixels, respectively.

8. The OLED display of claim 7, further comprising an input pad formed between the third common electrode and the substrate, the input pad configured to supply a voltage to the third common electrode.

9. The OLED display of claim 8, wherein each thin film transistor comprises a semiconductor layer, a gate electrode, a source electrode, and a drain electrode, and the input pad is formed in the same layer as one of the gate electrode, the source electrode, and the drain electrode of at least one of the thin film transistors.

10. The OLED display of claim 9, wherein the input pad is made of the same material as the one of the gate electrode, the source electrode, and the drain electrode of at least one of the thin film transistors.

11. An organic light emitting diode (OLED) display comprising:
a substrate;
a plurality of sub-pixels formed on the substrate, each of the sub-pixels having an emission layer configured to emit light;
a first common electrode formed on the emission layers of a first group of the sub-pixels; and
a second common electrode formed on the emission layers of a second group of the sub-pixels;
wherein the first and second common electrodes are electrically insulated from each other.

12. The OLED display of claim 11, wherein the first group of the sub-pixels comprises red sub-pixels.

13. The OLED display of claim 12, wherein the second group of the sub-pixels comprises blue and green sub-pixels.

14. The OLED display of claim 11, further comprising a third common electrode formed on the emission layers of a third group of the sub-pixels, wherein the third common electrode is electrically insulated from both the first and second common electrodes.

15. The OLED display of claim 14, wherein the first group of the sub-pixels comprises red sub-pixels.

16. The OLED display of claim 15, wherein the second group of the sub-pixels comprises green sub-pixels.

17. The OLED display of claim 16, wherein the third group of the sub-pixels comprises blue sub-pixels.

18. The OLED display of claim 14, further comprising an input pad formed between the third common electrode and the substrate, the input pad configured to supply a voltage to the third common electrode.

19. The OLED display of claim 18, further comprising a plurality of thin film transistors, wherein each thin film transistor comprises a semiconductor layer, a gate electrode, a source electrode, and a drain electrode, and the input pad is formed in the same layer as one of the gate electrode, the source electrode, and the drain electrode of at least one of the thin film transistors.

20. The OLED display of claim 19, wherein the input pad is made of the same material as the one of the gate electrode, the source electrode, and the drain electrode of at least one of the thin film transistors.
